(19) United States
(12) Patent Application Publication
(10) Pub. No.: US 2015/0230359 A1
(43) Pub. Date: Aug. 13, 2015

(54) CHIP CARD HOLDER AND PORTABLE ELECTRONIC DEVICE WITH SAME

(71) Applicant: Chiun Mai Communication Systems, Inc., New Taipei (TW)

(72) Inventors: HUNG-CHEN WU, New Taipei (TW); YU-CHUN HSIEH, New Taipei (TW)

(21) Appl. No.: 14/585,821

(22) Filed: Dec. 30, 2014

(30) Foreign Application Priority Data
Feb. 8, 2014 (CN) 201410045379.8

(51) Int. Cl. H05K 7/10; H05K 5/02; H05K 5/00

(52) U.S. Cl. CPC H05K 7/10; H05K 5/0091; H05K 5/0004; H05K 5/0221; H05K 5/023

(57) ABSTRACT

A chip card holder includes a tray and a sliding member. The tray is configured for receiving a chip card and defines at least one sliding hole. The sliding member includes at least one sliding portion. The at least one sliding portion is sildably received in the at least one sliding hole to adjust a distance between the tray and the sliding member.

### CROSS-REFERENCE TO RELATED APPLICATIONS

This application claims priority to Chinese Patent Application No. 201410045379.8 filed on Feb. 8, 2014, the contents of which are incorporated by reference herein.

### FIELD

The disclosure generally relates to a chip card holder and a portable electronic device with the chip card holder.

### BACKGROUND

Chip cards are widely used in portable electronic devices, such as mobile phones, to enhance or specialize the functions of the portable electronic devices. However, it can be difficult for the chip card to be removed from a casing of the portable electronic device.

### BRIEF DESCRIPTION OF THE DRAWINGS

Implementations of the present technology will now be described, by way of example only, with reference to the attached figures.

FIG. 1 is an exploded, isometric view of an embodiment of a portable electronic device having a chip card holder.

FIG. 2 is an exploded, isometric view of the chip card holder of FIG. 1.

FIG. 3 is an assembled, isometric view of the portable electronic device of FIG. 1.

FIG. 4 is similar to FIG. 3, but shown from another angle.

FIG. 5 is a partially assembled view of the chip card holder of FIG. 2, showing a sliding member in a first state.

FIG. 6 is similar to FIG. 5, but showing the sliding member in a second state.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

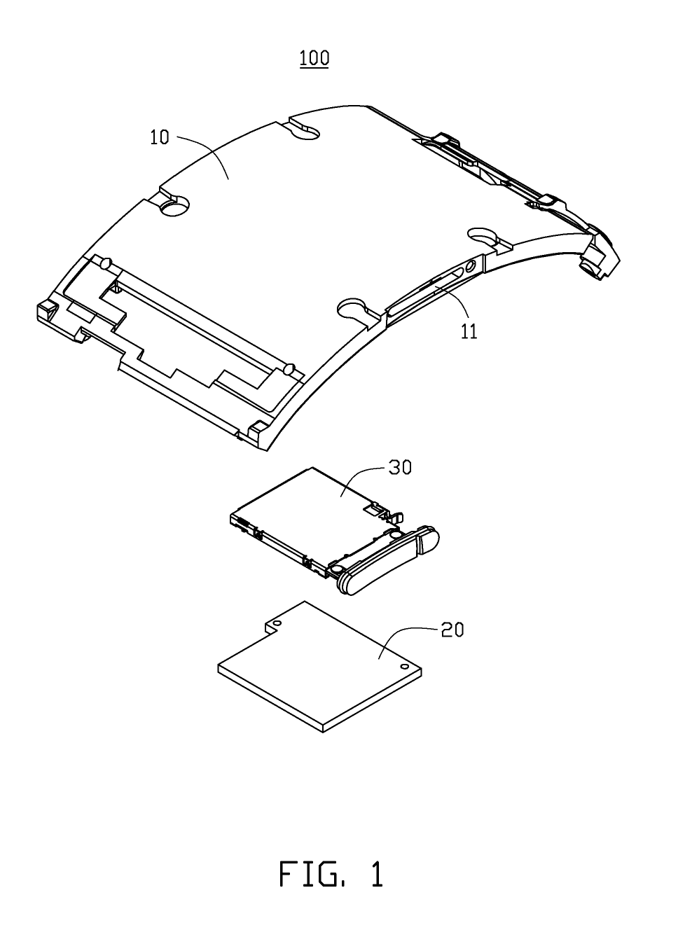

FIG. 1 illustrates an embodiment of a portable electronic device 100. The portable electronic device 100 may be a mobile phone or any portable electronic device using a chip card. The chip card can be a subscriber identity module (SIM) card, a memory card, or a multimedia card (MMC). The portable electronic device 100 includes a main body 10, a circuit board 20, and a chip card holder 30.

In this embodiment, the main body 10 is a dial of a watch. The main body 10 is configured to receive the circuit board 20 and the chip card holder 30. A side surface of the main body 10 defines a recess 11. The recess 11 is configured to receive the chip card holder 30. The circuit board 20 is positioned in the recess 11 and is electrically connected to the chip card.

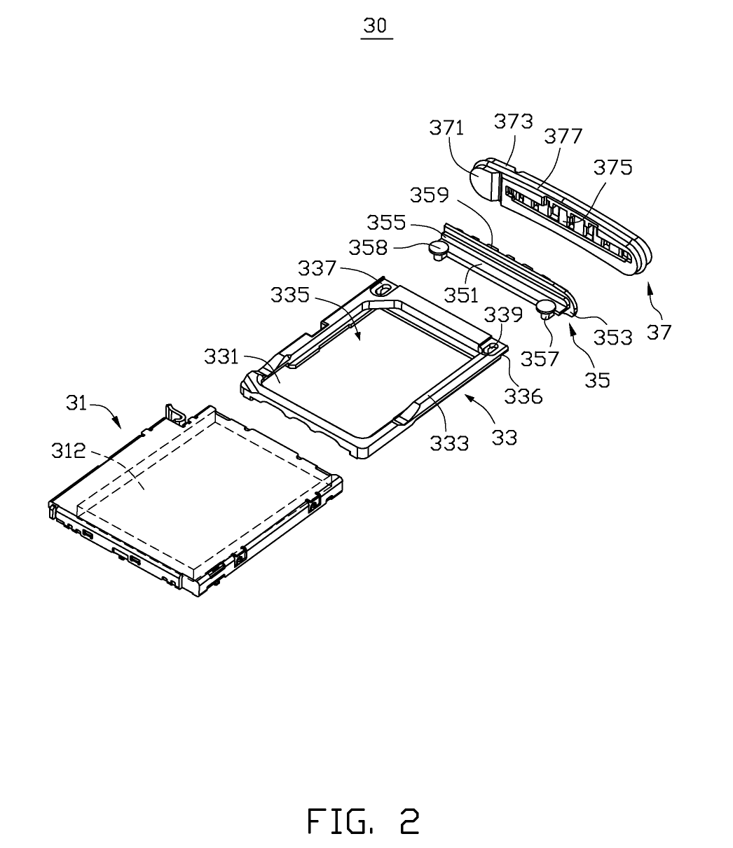

FIG. 2 illustrates that the chip card holder 30 includes a receiving frame 31, a tray 33, a sliding member 35, and a handle member 37. The receiving frame 31 is located in the recess 11 and forms a receiving space 312 for receiving the tray 33. In this embodiment, an entrance of the receiving space 312 is aligned with and in communication with an entrance of the recess 11.

The tray 33 is slidably received in the receiving space 312 of the receiving frame 31. The tray 33 is configured to support the chip card and bring the chip card into or out of the receiving space 312. The tray 33 includes a bottom wall 331 and a number of sidewalls 333. The sidewalls 333 extend substantially perpendicularly from a periphery of the bottom wall 331 and define an accommodating space 335 with the bottom wall 331 for accommodating the chip card.

A bottom surface of one of the sidewalls 333 away from the entrance of the receiving space 312 defines a sliding slot 336. A top surface of the sidewall 333 defining the sliding slot 336 further defines at least one opening 337. In this embodiment, there are two openings 337. The two openings 337 are positioned at two opposite ends of the sidewall 333 defining the sliding slot 336. A middle portion of each opening 337 defines a sliding hole 339. The sliding hole 339 is in communication with the sliding slot 336.

The sliding member 35 is mounted to the tray 33 and can slide relative to the tray 33, thereby a distance between the sliding member 35 and the tray 33 can be adjusted. The sliding member 35 includes a bottom board 351, a side board 353, a middle board 355, at least one sliding portion 357, and at least one clasp portion 358. The bottom board 351 is substantially rectangular and can be slidably mounted in the sliding slot 336 of the tray 33. The side board 353 is perpendicularly positioned at a side of the bottom board 351. At least one latching block 359 protrudes from one side of the side board 353 away from the bottom board 351. The at least one latching block 359 is configured to secure the sliding member 35 to the handle member 37. The middle board 355 is substantially perpendicularly mounted on one side edge of the bottom board 351 and abuts one side surface of the side board 353. The middle board 355 is configured to limit movement of the tray 33.

In this embodiment, the sliding member 35 includes two sliding portions 357 and two clasp portions 358. The two sliding portions 357 are positioned at another side edge of the bottom board 351 away from the side board 353. The two sliding portion 357 are assembled to the sliding hole 339 and can slide in the sliding hole 339. Each of the two clasp portions 358 protrudes from a top portion of the sliding portion 357. When the sliding portions 357 are assembled to the sliding holes 339, the clasp portions 358 latch the periphery of the openings 337 to prevent the sliding portion 357 from sliding out of the sliding holes 339.

The handle member 37 is attached to one side of the sliding member 35. The handle member 37 includes a bottom surface 371 and a peripheral wall 373. The bottom surface 371 defines at least one latching slot 375. The latching slot 375 is configured to receive the latching block 359, thereby latching the handle member 37 to the sliding member 35. The peripheral wall 373 is substantially perpendicularly connected to a periphery of the bottom surface 371. At least one flange 377 protrudes from the peripheral wall 373. The at least one flange 3357 facilitates a user's fingertip to actuate the handle member 37 to pull out the sliding member 35 and the tray 33 from the recess 11.

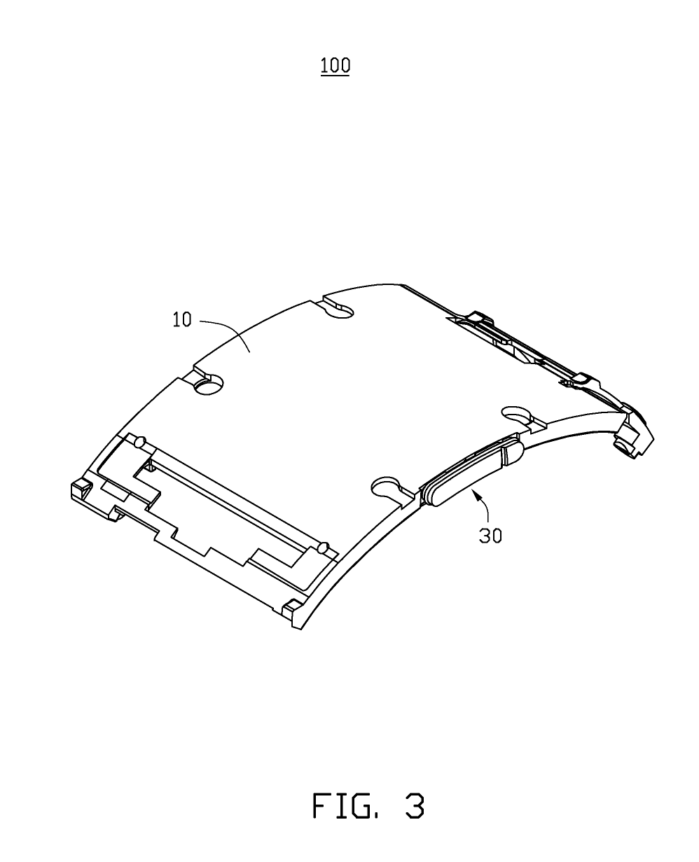

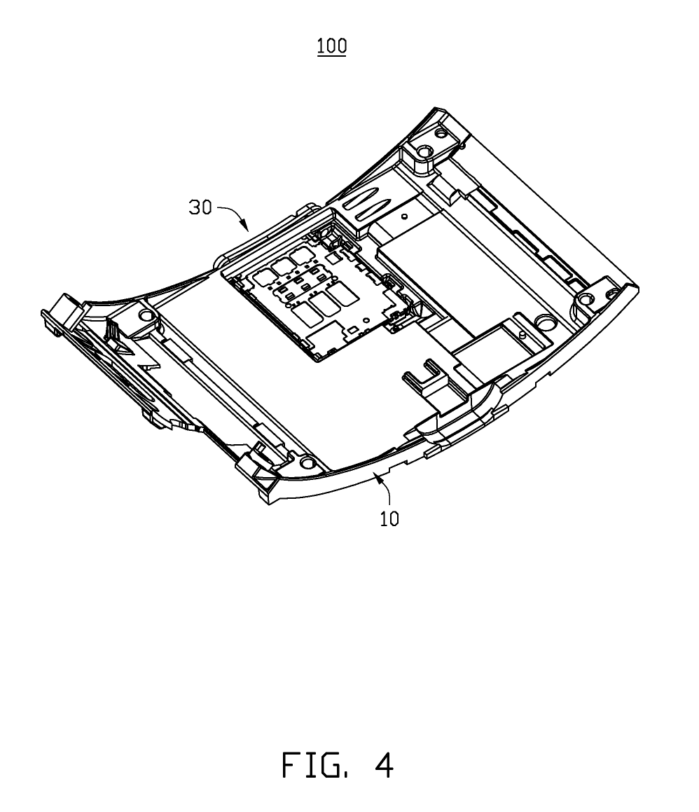

Referring to FIGS. 3-4, in assembly, the receiving frame 31 is mounted on the circuit board 20 with an entrance of the receiving space 312 of the receiving frame 31 being aligned with and in communication with an entrance of the recess 11 of the main body 10. The latching blocks 359 of the sliding member 35 are latched in the latching slots 375 of the handle member 37. Then, the handle member 37 is assembled to the sliding member 35. The sliding portions 357 of the sliding member 35 are aligned with the sliding holes 339. Then, the sliding portions 357 of the sliding member 35 pass through the sliding holes 339 and the clasp portions 358 are clasped with the openings 337, thereby the sliding portions 357 of the sliding member 35 are prevented from sliding out of the sliding holes 339. In this way, the sliding member 35 is slidably mounted to the tray 33 with the sidewall 333 defining the sliding slot 336 resisting the middle board 355. The tray 33 is aligned with the entrance of the recess 11 of the main body 10. Then, the handle member 37 is operated and the tray 33 is pushed towards the recess 11 until the tray 33 passes through the entrance of the recess 11 and is received in the receiving space 312, and the handle member 37 is mounted in the entrance of the recess 11.

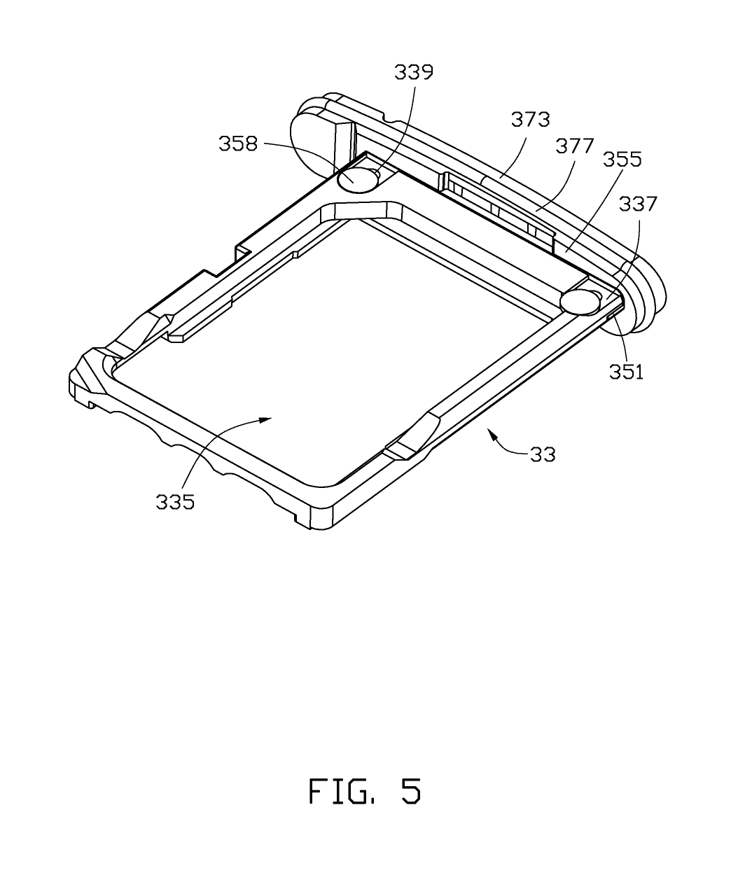

Referring to FIG. 5, when the chip card holder 30 is assembled to the main body 10, the sidewall 333 defining the sliding slot 336 and the sliding holes 339 resists the middle board 355 of the sliding member 35. Thus, there is no gap between the tray 33 and the sliding member 35.

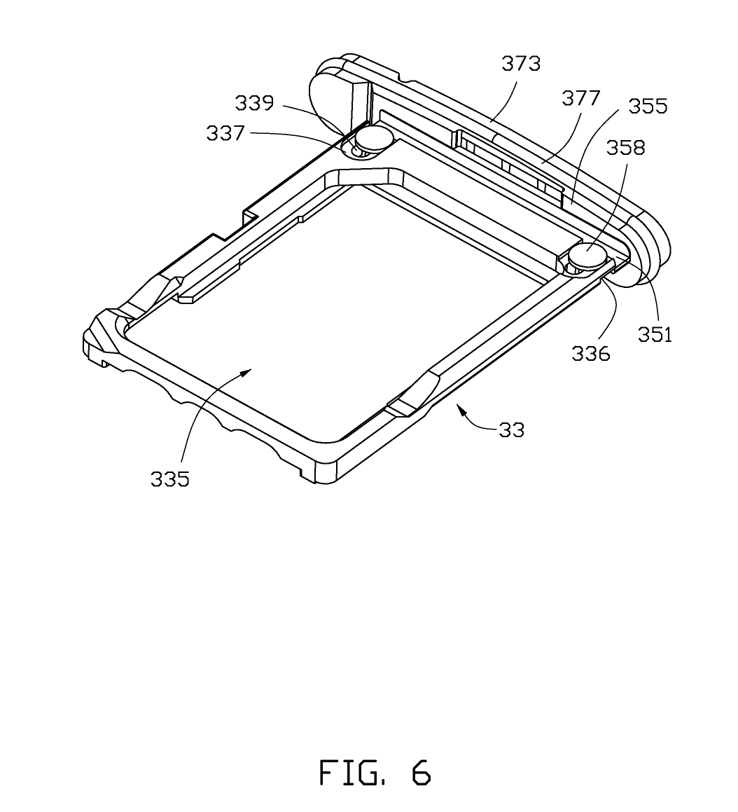

Referring to FIG. 6, to mount the chip card into the chip card holder 30 or to change the chip card, the flange 377 of the handle member 37 is operated. The bottom board 351 of the sliding member 35 is slid along the sliding slot 336 and the sliding portions 357 are slid in the sliding holes 339. Then, the sliding member 35 moves away from the tray 33, thereby a gap is formed between the sliding member 35 and the tray 33. The tray 33 is then manually pulled out of the receiving space 312 of the receiving frame 31 and is removed from the main body 10 due to the gap. The chip card can now be easily mounted to or removed from the tray 30.

The embodiments shown and described above are only examples. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A chip card holder comprising:
a tray configured for receiving a chip card and defining at least one sliding hole; and
a sliding member comprising at least one sliding portion;
wherein the at least one sliding portion is sildably received in the at least one sliding hole to adjust a distance between the tray and the sliding member.

2. The chip card holder of claim 1, wherein the tray comprises a bottom wall and a number of sidewalls, the sidewalls extend substantially perpendicularly from a periphery of the bottom wall and define an accommodating space with the bottom wall for accommodating the chip card.

3. The chip card holder of claim 2, wherein one of the sidewalls defines a sliding slot, the sliding member comprises a bottom board, the bottom board is slidably mounted in the sliding slot, and the at least one sliding portion is positioned at one side of the bottom board.

4. The chip card holder of claim 3, wherein the sidewall defining the sliding slot further defines at least one opening, the at least one sliding hole is defined at a middle portion of the opening, the sliding member further comprises at least one clasp portion, the at least one clasp portion is protruded from the sliding portion and latches the periphery of the opening.

5. The chip card holder of claim 3, further comprising a handle member, wherein the handle member is mounted to one side of the sliding member away from the tray.

6. The chip card holder of claim 5, wherein the sliding member further comprises a side board, the side board is perpendicularly located at a side of the bottom board, one side of the side board away from the bottom board protrudes at least one latching block, the handle member defines at least one latching slot, the at least one latching block is latched in the latching slot to mount the handle member to the sliding member.

7. The chip card holder of claim 6, wherein the handle member comprises a bottom surface and a peripheral wall, the at least one latching slot is defined at the bottom surface, the peripheral wall is substantially perpendicularly connected to a periphery of the bottom surface and at least one flange is protruded from the peripheral wall.

8. The chip card holder of claim 6, wherein the sliding member further comprises a middle board, the middle board is substantially perpendicularly mounted on one side of the bottom board and abuts a side of the side board.

9. The chip card holder of claim 1, further comprising a receiving frame, wherein the receiving frame defines a receiving space for receiving the tray.

10. A portable electronic device comprising:
a main body defining a recess; and
a chip card holder slidably received in the recess; the chip card holder comprising:
a tray configured for receiving a chip card and defining at least one sliding hole; and
a sliding member comprising at least one sliding portion;
wherein the at least one sliding portion is sildably received in the at least one sliding hole to adjust a distance between the tray and the sliding member.

11. The portable electronic device of claim 10, further comprising a circuit board, wherein the circuit board is positioned in the recess, and the chip card holder is located on the circuit board.

12. The portable electronic device of claim 10, wherein the tray comprises a bottom wall and a number of sidewalls, the sidewalls extend substantially perpendicularly from a periphery of the bottom wall and define an accommodating space with the bottom wall for accommodating the chip card.

13. The portable electronic device of claim 12, wherein one of the sidewalls defines a sliding slot, the sliding member comprises a bottom board, the bottom board is slidably mounted in the sliding slot, and the at least one sliding portion is positioned at an end of the bottom board.

14. The portable electronic device of claim 13, wherein the sidewall defining the sliding slot further defines at least one opening, the at least one sliding hole is defined at a middle portion of the opening, the sliding member further comprises at least one clasp portion, the at least one clasp portion is protruded from the sliding portion and latches the periphery of the opening.

15. The portable electronic device of claim 13, further comprising a handle member, wherein the handle member is mounted to an end of the sliding member away from the tray.

16. The portable electronic device of claim 15, wherein the sliding member further comprises a side board, the side board is perpendicularly located at a side of the bottom board, one side of the side board away from the bottom board protrudes at least one latching block, the handle member defines at least one latching slot, the at least one latching block is latched in the latching slot to mount the handle member to the sliding member.

17. The portable electronic device of claim 16, wherein the handle member comprises a bottom surface and a peripheral wall, the at least one latching slot is defined at the bottom surface, the peripheral wall is substantially perpendicularly connected to a periphery of the bottom surface and at least one flange is protruded from the peripheral wall.

18. The portable electronic device of claim 16, wherein the sliding member further comprises a middle board, the middle board is substantially perpendicularly mounted on an end of the bottom board and abuts a side surface of the side board.

19. The portable electronic device of claim 10, further comprising a receiving frame, wherein the receiving frame defines a receiving space for receiving the tray.
